(19) United States
(12) Patent Application Publication
(10) Pub. No.: US 2019/0096930 A1
(43) Pub. Date: Mar. 28, 2019

(54) SEMICONDUCTOR IMAGE SENSOR

(71) Applicant: TAIWAN SEMICONDUCTOR MANUFACTURING COMPANY LTD., HSINCHU (TW)

(72) Inventors: CHUN-HAO CHUANG, HSINCHU CITY (TW); KENG-YU CHOU, KAOHSIUNG CITY (TW); WEN-HAU WU, NEW TAIPEI CITY (TW); WEI-CHIEH CHIANG, CHANGHUA COUNTY (TW); CHIEN-HSIEN TSENG, HSINCHU (TW); KAZUAKI HASHIMOTO, HSINCHU COUNTY (TW)

(21) Appl. No.: 15/873,355

(22) Filed: Jan. 17, 2018

Related U.S. Application Data
(60) Provisional application No. 62/563,298, filed on Sep. 26, 2017.

(51) Int. Cl. H01L 27/146

(52) U.S. Cl. CPC H01L 27/1463; H01L 27/1464; H01L 27/14621; H01L 27/14627; H01L 27/14636; H01L 27/1462; H01L 27/14625; H01L 27/14645; H01L 27/14685

(57) ABSTRACT

A BSI image sensor includes a substrate including a front side and a back side opposite to the front side, and a plurality of pixel sensors arranged in an array. Each of the pixel sensors includes a photo-sensing device in the substrate, a color filter over the pixel sensor on the back side, and an optical structure over the color filter on the back side. The optical structure includes a first sidewall, and the first sidewall and a plane substantially parallel with a front surface of the substrate form an included angel greater than 0°.

### PRIORITY DATA

This patent claims the benefit of U.S. Provisional Patent Application Ser. No. 62/563,298 filed Sep. 26, 2017, the entire disclosure of which is hereby incorporated by reference.

### BACKGROUND

Digital cameras and other imaging devices employ images sensors. Image sensors convert optical images to digital data that may be represented as digital images. An image sensor includes an array of pixel sensors and supporting logic circuits. The pixel sensors of the array are unit devices for measuring incident light, and the supporting logic circuits facilitate readout of the measurements. One type of image sensor commonly used in optical imaging devices is a back side illumination (BSI) image sensor. BSI image sensor fabrication can be integrated into conventional semiconductor processes for low cost, small size, and high integration. Further, BSI image sensors have low operating voltage, low power consumption, high quantum efficiency, low read-out noise, and allow random access.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a pixel sensor of a BSI image sensor according to aspects of the present disclosure in one or more embodiments.

FIGS. 2A-2E are a series of cross-sectional views of pixel sensors of a BSI image sensor at various fabrication stages constructed according to aspects of the present disclosure in one or more embodiments.

FIG. 3 is a cross-sectional view of a pixel sensor of a BSI image sensor according to aspects of the present disclosure in one or more embodiments.

FIGS. 4A-4B are a series of cross-sectional views of pixel sensors of a BSI image sensor at various fabrication stages constructed according to aspects of the present disclosure in one or more embodiments.

FIG. 5 is a cross-sectional view of a pixel sensor of a BSI image sensor according to aspects of the present disclosure in one or more embodiments.

FIGS. 6A-6B are a series of cross-sectional views of pixel sensors of a BSI image sensor at various fabrication stages constructed according to aspects of the present disclosure in one or more embodiments.

FIG. 7 is a cross-sectional view of a pixel sensor of a BSI image sensor according to aspects of the present disclosure in one or more embodiments.

FIG. 8 is a cross-sectional view of a pixel sensor of a BSI image sensor according to aspects of the present disclosure in one or more embodiments.

FIG. 9 is a cross-sectional view of pixel sensors of a BSI image sensor according to aspects of the present disclosure in one or more embodiments.

FIG. 10 is a cross-sectional view of a pixel sensor of a BSI image sensor according to aspects of the present disclosure in one or more embodiments.

FIG. 11 is a cross-sectional view of a pixel sensor of a BSI image sensor according to aspects of the present disclosure in one or more embodiments.

FIG. 12 is a cross-sectional view of a pixel sensor of a BSI image sensor according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

As used herein, “micro structures” refer to recessed or protruded structures that make an uneven or a rough surface of the substrate or the color filters. As used herein, a “recess” is a structure recessed from a perimeter or an edge of another structure, and a “protrusion” is a structure protruded from a perimeter or an edge of another structure.

BSI image sensor includes an array of pixel sensors. Typically, BSI image sensors include an integrated circuit having a semiconductor substrate and photodiodes corresponding to the pixel sensors arranged within the substrate, a back-end-of-line (BEOL) metallization of the integrated circuits disposed over a front side of the substrate, and an optical stack including color filters and micro-lenses corresponding to the pixel sensors disposed over a back side of the substrate. As the size of BSI image sensors decrease, BSI image sensors face a number of challenges. One challenge with BSI image sensors is cross talk between neighboring pixel sensors, and another challenge with BSI image sensors is light collection. As BSI image sensors become smaller and smaller, the surface area for light collection becomes smaller and smaller, thereby reducing the sensitivity of pixel sensors. This is problematic for low light environments. Therefore, it is in need to increase absorption efficiency of the pixel sensors and angular response such that the sensitivity of BSI image sensors is improved.

The present disclosure therefore provides a pixel sensor of a BSI image sensor including an insulating structure including a curved surface protruded toward a front side of the BSI sensor, thus light is further condensed in some embodiments. The present disclosure further provides a BSI image sensor including an optical structure including a material the same with color filers or micro-lenses. The optical structure serves as a light guide, and longer light traveling distance is created by the optical structure in some embodiments. Accordingly, more photons are absorbed. Further, the disclosure further provides a BSI image sensor including a plurality of micro-lens over one color filter, and longer light traveling distance is created by the plurality of micro-lens in some embodiments. In other words, since light is traveling with large angle in the pixel sensor, the sensitivity and angular response are improved.

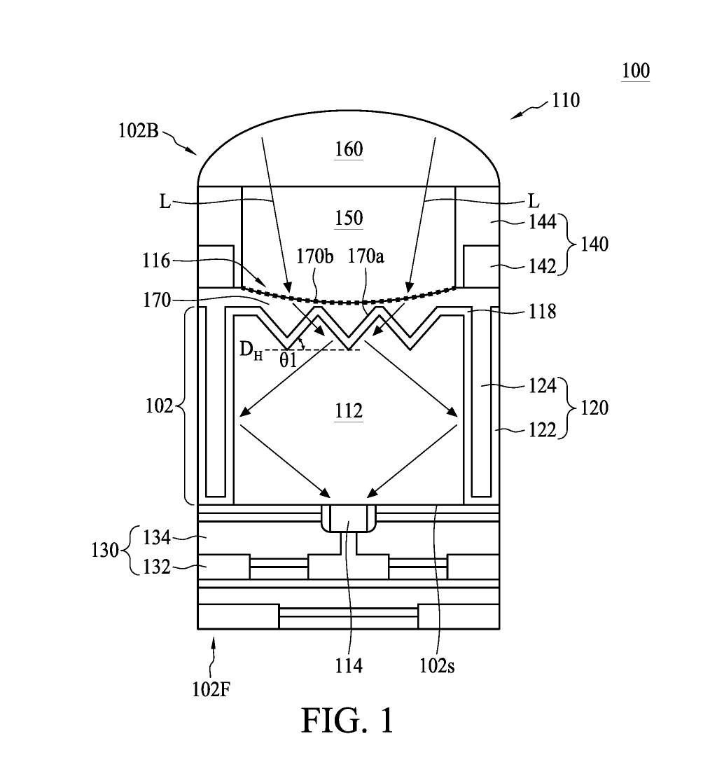

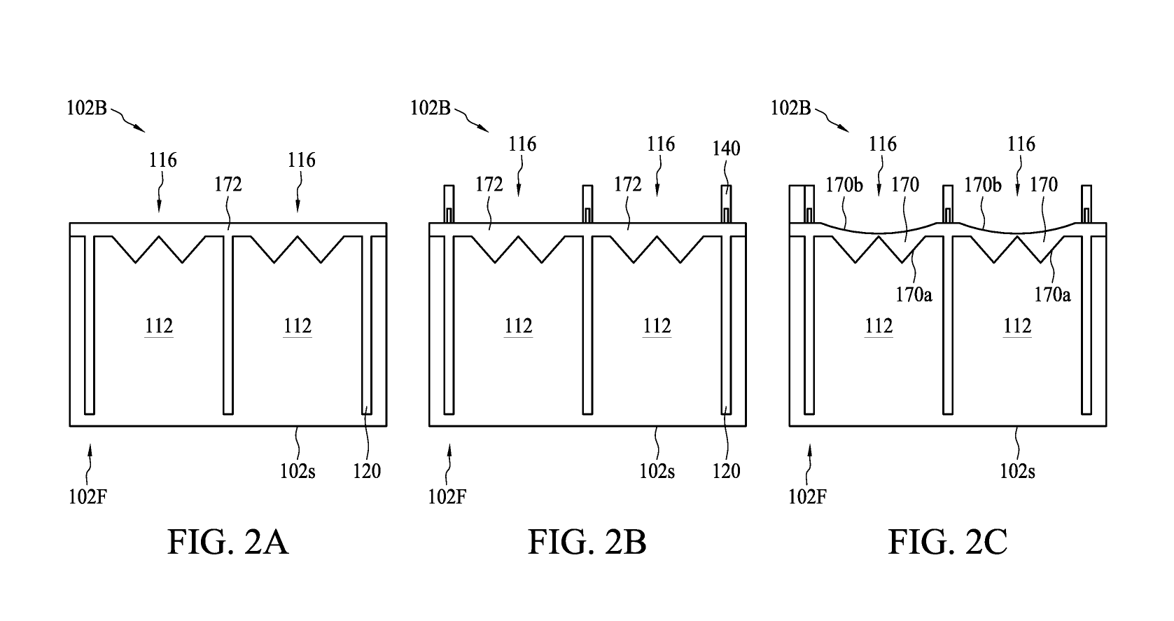

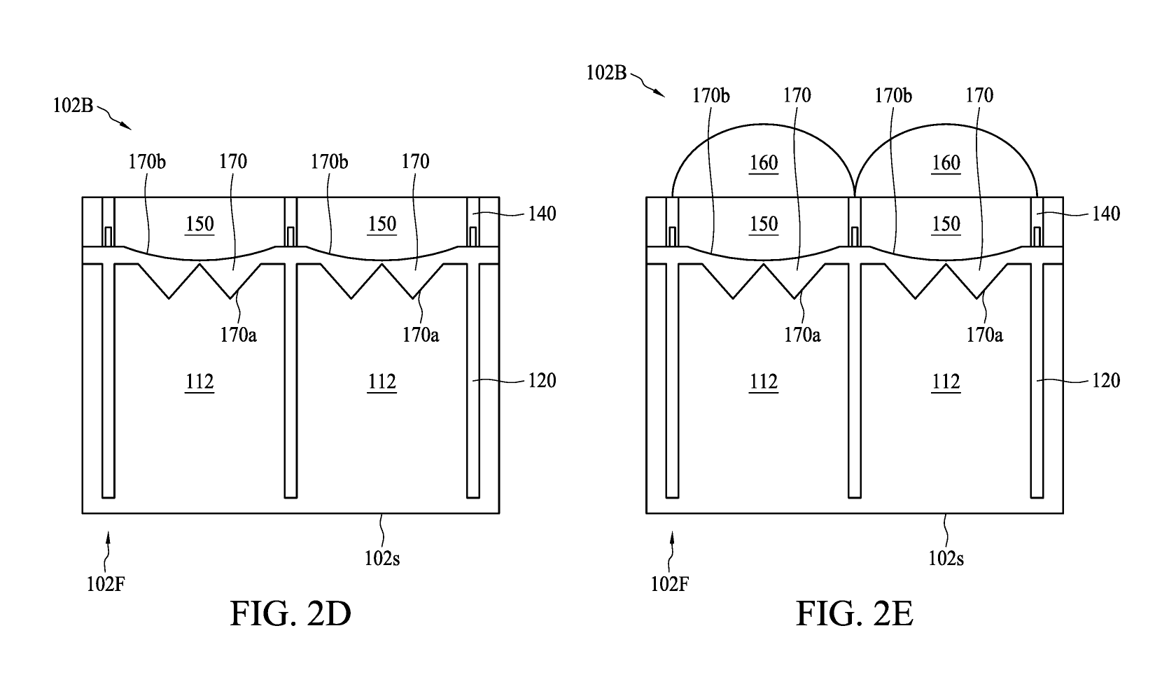

FIG. 1 is a cross-sectional view of a pixel sensor 110 of a BSI image sensor 100 according to aspects of the present disclosure in some embodiments, and FIGS. 2A-2E are a series of cross-sectional views of pixel sensors of a BSI image sensor at various fabrication stages constructed according to aspects of the present disclosure in one or more embodiments. It should be easily understood that same elements in FIG. 1 and FIGS. 2A-2E are designated by the same numerals. As shown in FIG. 1, the BSI image sensor 100 includes a substrate 102, and the substrate 102 includes, for example but not limited to, a bulk semiconductor substrate such as a bulk silicon (Si) substrate, or a silicon-on-insulator (SOI) substrate. The substrate 102 has a front side 102F and a back side 102B opposite to the front side 102F. The BSI image sensor 100 includes a plurality of pixel sensors 110 typically arranged within an array, and each of the pixel sensors 110 includes a light-sensing device such as a photodiode 112 disposed in the substrate 102. In other words, the BSI image sensor 100 includes a plurality of photodiodes 112 corresponding to the pixel sensors 110. The photodiodes 112 are arranged in rows and columns in the substrate 102, and configured to accumulate charge (e.g. electrons) from photons incident thereon. Further, logic device, such as transistor 114, can be disposed over the substrate 102 on the front side 102F and configured to enable readout of the photodiodes 112. The pixel sensor 110 is disposed to receive light with a predetermined wavelength. Accordingly, the photodiodes 112 can be operated to sense visible light of incident light in some embodiments. Or, the photodiode 112 can be operated to sense infrared (IR) and/or near-infrared (NIR) of the incident light in some embodiments.

An isolation structure 120 such as a deep trench isolation (DTI) structure is disposed in the substrate 102 as shown in FIG. 1. In some embodiments, the DTI structure 120 can be formed by the following operations. For example, a first etch is performed from the back side 102B of the substrate 102. The first etch results in a plurality of deep trenches (not show) surrounding and between the photodiodes 112. An insulating material such as silicon oxide (SiO) is then formed to fill the deep trenches using any suitable deposition technique, such as chemical vapor deposition (CVD). In some embodiments, at least sidewalls of the deep trenches are lined by a coating 122 and the deep trenches are then filled up by an insulating material 124. The coating 122 may include a metal such tungsten (W), copper (Cu), or aluminum-copper (AlCu), or a low-n material, which has a refractive index (n) less than silicon. The low-n material can include SiO or hafnium oxide (HfO), but the disclosure is not limited to this. In some embodiments, the insulating material 124 filling the deep trenches can include the low-n insulating material. A planarization is then performed to remove superfluous insulating material, thus the surface of the substrate 102 on the back side 102B is exposed, and the DTI structure 120 surrounding and between the photodiodes 112 is obtained as shown in FIG. 1. The DTI structure 120 provides optical isolation between neighboring pixel sensors 110, thereby serving as a substrate isolation grid and reducing cross-talk.

A back-end-of-line (BEOL) metallization stack 130 is disposed over the front side 102F of the substrate 102. The BEOL metallization stack 130 includes a plurality of metallization layers 132 stacked in an interlayer dielectric (ILD) layer 134. One or more contacts of the BEOL metallization stack 130 is electrically connected to the logic device 114. In some embodiments, the ILD layer 134 can include a low-k dielectric material (i.e., a dielectric material with a dielectric constant less than 3.9) or an oxide, but the disclosure is not limited to this. The plurality of metallization layers 132 may include a metal such as copper (Cu), tungsten (W), or aluminum (Al), but the disclosure is not limited to this. In some embodiments, another substrate (not shown) can be disposed between the metallization structure 130 and external connectors such as a ball grid array (BGA) (not shown). And the BSI image sensor 100 is electrically connected to other devices or circuits through the external connectors, but the disclosure is not limited to this.

Referring to FIG. 1, in some embodiments, a plurality of color filters 150 corresponding to the pixel sensors 110 is disposed over the pixel sensors 110 on the back side 102B of the substrate 102. In other words, each of the pixel sensors 110 includes a color filter 150 over the photo-sensing device 112 on the back side 102B. Further, a low-n structure 140 is disposed between the color filters 150 in some embodiments. In some embodiments, the low-n structure 140 includes a grid structure and the color filters 150 are located within the grid. Thus the low-n structure 140 surrounds each color filter 150, and separates the color filters 150 from each other as shown in FIG. 1. The low-n structure 140 can be a composite structure including layers with a refractive index less than the refractive index of the color filters 150. In some embodiments, the low-n structure 140 can include a composite stack including at least a metal layer 142 and a dielectric layer 144 disposed over the metal layer 142. In some embodiments, the metal layer 142 can include W, Cu, or AlCu. The dielectric layer 144 includes a material with a refractive index less than the refractive index of the color filter 150 or a material with a refractive index less than a refractive index of Si, but the disclosure is not limited to this. Due to the low refractive index, the low-n structure 140 serves as a light guide to direct or reflect light to the color filters 150. Consequently, the low-n structure 140 effectively increases the amount of the light incident into the color filters 150. Further, due to the low refractive index, the low-n structure 140 provides optical isolation between neighboring color filters 150.

Each color filter 150 is disposed over each of the corresponding photodiodes 112. The color filters 150 are assigned to corresponding colors or wavelengths of lights, and configured to filter out all but the assigned colors or wavelengths of lights. Typically, the color filters 150 assignments alternate between red, green, and blue lights, such that the color filters 150 include red color filters, green color filters and blue color filters. In some embodiments, the red color filters, the green color filters and the blue color filters are arranged in a Bayer mosaic pattern, but the disclosure is not limited to this. In some embodiments, a micro-lens 160 corresponding to each pixel sensor 110 is disposed over the color filter 150. It should be easily understood that locations and areas of each micro-lens 160 correspond to those of the color filter 150 or those of the pixel sensor 110 as shown in FIG. 1.

In some embodiments, each of the pixel sensors 110 includes a plurality of micro structures 116 disposed over the back side 102B of the substrate 102 as shown in FIG. 1. In some embodiments, the micro structures 116 can be formed by following operations. A mask layer (not shown) is disposed over the surface of the substrate 102 on the back side 102B, and followed by forming a patterned photoresist (not shown) over the mask layer. The substrate 102 is then etched through the patterned photoresist and the mask layer from the back side 102B, and thus the plurality of micro structures 116 is formed over the back side 102B of the substrate 102 within each of the pixel sensors 110. Then the patterned photoresist and the mask layer are removed. In some embodiments, further operations such as a wet etch, can be taken. As a result, upper and lower portions of the micro structures 116 are tapered or rounded to obtain a wave pattern as shown in FIG. 1. In some embodiments, a sidewall of the micro structures 116 and a direction or a plane D_{H} form an included angle θ1. In some embodiments, the plane D_{H} is substantially parallel with a front surface 102s of the substrate 102. In some embodiments, the included angle θ1 is between about 48° and about 58°, but the disclosure is not limited to this. In some embodiments, the micro structures 116 can be continuous structures and include a wave profile as shown in FIG. 1. In some embodiments, the micro structures 116 can include discrete structure spaced apart from each other by the substrate 102.

In some embodiments, an anti-reflective coating (ARC) 118 is disposed over the substrate 102 on the back side 102B. And surfaces of the micro structures 116 are lined by the conformally formed ARC 118. In some embodiments, an insulating structure 170 is disposed over the ARC 118 on the back side 102B of the substrate 102, the insulating structure 170 includes a first surface 170a facing the front side 102F and a second surface 170b facing the back side 102B. The first surface 170a of the insulating structure 170 includes a profile the same with the micro structures 116. More importantly, the second surface 170b includes a curved surface dented or curved toward the front side 102F.

Referring to FIGS. 2A-2E, the insulating structure 170 can be formed by the following operations. For example, an insulating material 172 is disposed over the micro structures 116 and the ARC 118 (not shown in FIGS. 2A-2E) on the back side 102B of the substrate 102. As shown in FIG. 2A, the insulating material 172 fills spaces between the micro structures 116, and a planarization process such as CMP can be operate to the insulating material 172 to provide a substantially flat or even surface over the back side 102B of the substrate 102. In some embodiments, the insulating material 172 can include, for example, an oxide such as silicon dioxide, but the disclosure is not limited to this.

Referring to FIG. 2B, next, the low-n structure 140 is disposed over the insulating material 172. As mentioned above, the low-n structure 140 includes a grid structure so that the color filters 150 are to be located within the grid. Referring to FIG. 2C, an etching is performed to the insulating material 172, and thus a curved surface dented or curved toward the front side 102F is formed. Consequently, the insulating structure 170 is obtained. The insulating structure 170 includes the first surface 170a covering the micro structures 116 and having a wave pattern the same with the micro structures 116 in a cross-sectional view. The insulating structure 170 further includes the second surface 170b including the curved surface curved toward the front side 102F as shown in FIG. 2C. Thereafter, the color filters 150 are disposed within the low-n structure 140 as shown in FIG. 2D, and followed by disposing the micro-lens 160 over each of the color filters 150 as shown in FIG. 2E. Accordingly, the insulating structure 170 is sandwiched between the substrate 102 and the optical structure (including the color filter 150 and the micro-lens 160). And the first surface 107a of the insulating structure 170 faces the substrate 102 while the second surface 170b faces the optical structure 150/160. Additionally, the color filter 150 disposed over the second surface 170b include a flat surface facing the micro-lens 160 and a curved surface facing the insulating structure 170.

Referring back to FIG. 1, the incident light L is condensed to by the micro-lens 160 over each color filter 150 and then converged to the color filter 150. However, the incident light L passing the insulating structure 170 is further condensed due to the curved second surface 170b. In other words, more light can be collected by the optical structure (including the micro-lens 160 and the color filter 150) and the insulating structure 170. Further, the condensed light is scattered or diffused by the micro structures 116, and thus the direct incident light is dipped or tilted by the micro structures 116 when entering the photodiode 112. Accordingly, longer light traveling distance is created in the photodiode 112. Further, light can be reflected back to the photodiode 112 by the DTI structure 120. In other words, light is trapped in the photodiode 112, and sensitivity of the pixel sensor 110 is therefore improved. Additionally, since the light traveling distance is extended, a thickness of the photodiode 112 or the substrate 102 can be reduced and thus process is further simplified and improved.

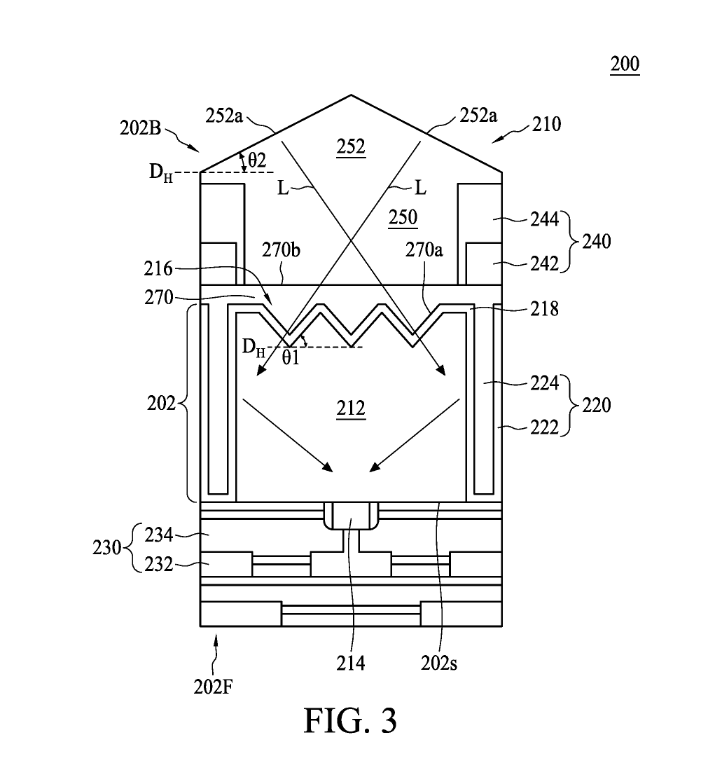

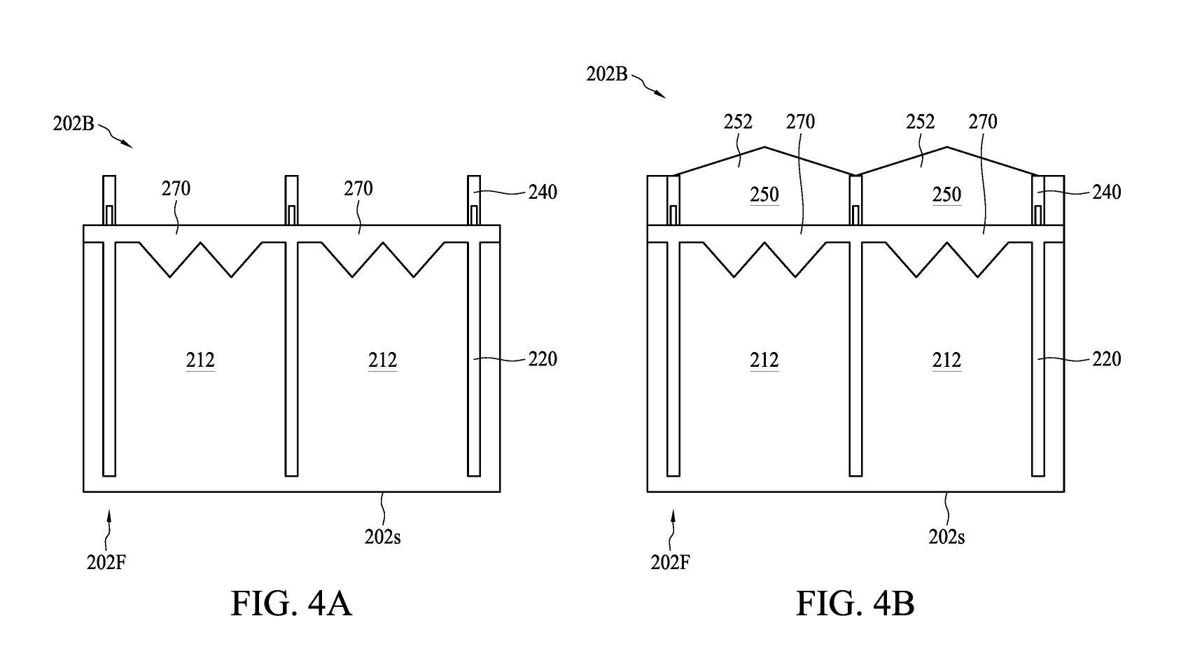

FIG. 3 is a cross-sectional view of a pixel sensor 210 of a BSI image sensor 200 according to aspects of the present disclosure in one or more embodiments, and FIGS. 4A-4B are a series of cross-sectional views of pixel sensors 210 of a BSI image sensor 200 at various fabrication stages constructed according to aspects of the present disclosure in one or more embodiments. It should be easily understood that same elements in FIG. 3 and FIGS. 4A-4E are designated by the same numerals. And elements the same in the BSI image sensor 100 and the BSI image sensor 200 can include the same material and/or formed by the same operations, and thus those details are omitted in the interest of brevity. As shown in FIG. 3, the BSI image sensor 200 includes a substrate 202, and the substrate 202 has a front side 202F and a back side 202B opposite to the front side 202F. The BSI image sensor 200 includes a plurality of pixel sensors 210 typically arranged within an array. A plurality of photo-sensing devices such as photodiodes 212 corresponding to the pixel sensors 210 is disposed in the substrate 202. The photodiodes 212 are arranged in rows and columns in the substrate 202. In other words, each of the pixel sensors 210 includes a photo-sensing device such as the photodiode 212. Further, logic device, such as transistor 214, is disposed over the front side 202F of the substrate 202 and configured to enable readout of the photodiode 212.

An isolation structure 220 such as a DTI structure is disposed in the substrate 202 as shown in FIG. 3. In some embodiments, at least sidewalls of the deep trenches are lined by a coating 222 and the deep trenches are filled up by an insulating material 224. The DTI structure 220 provides optical isolation between neighboring pixel sensors 210, thereby serving as a substrate isolation grid and reducing cross-talk. A BEOL metallization stack 230 is disposed over the front side 202F of the substrate 202. The BEOL metallization stack 230 includes a plurality of metallization layers 232 stacked in an ILD layer 234. One or more contacts of the BEOL metallization stack 230 is electrically connected to the logic device 214. In some embodiments, another substrate (not shown) can be disposed between the metallization structure 230 and external connectors such as a ball grid array (BGA) (not shown). And the BSI image sensor 200 is electrically connected to other devices or circuits through the external connectors, but the disclosure is not limited to this.

Referring to FIG. 3, in some embodiments, a plurality of color filters 250 corresponding to the pixel sensors 210 is disposed over the pixel sensors 210 on the back side 202B of the substrate 202. In other words, each of the pixel sensors 210 includes a color filter 250 over the photo-sensing device 212 on the back side 202B. Further, a low-n structure 240 is disposed between the color filters 250 in some embodiments. As mentioned above, the low-n structure 240 includes a grid structure and the color filters 250 are located within the grid. Thus the low-n structure 240 surrounds each color filter 250, and separates the color filters 250 from each other as shown in FIG. 3. The low-n structure 240 can be a composite structure including layers with a refractive index less than the refractive index of the color filters 250. In some embodiments, the low-n structure 240 can include a composite stack including at least a metal layer 242 and a dielectric layer 244 disposed over the metal layer 242. Due to the low refractive index, the low-n structure 240 serves as a light guide to direct or reflect light to the color filters 250. Consequently, the low-n structure 240 effectively increases the amount of the light incident into the color filters 250. Further, due to the low refractive index, the low-n structure 240 provides optical isolation between neighboring color filters 250. Each of the color filters 250 is disposed over each of the corresponding photodiodes 212. The color filters 250 are assigned to corresponding colors or wavelengths of lights, and configured to filter out all but the assigned colors or wavelengths of lights.

In some embodiments, each of the pixel sensors 210 includes a plurality of micro structures 216 disposed over the back side 202B of the substrate 202 as shown in FIG. 3. In some embodiments, the micro structures 216 are tapered or rounded to obtain a wave pattern as shown in FIG. 3. As mentioned above, a sidewall of the micro structures 216 and a direction or a plane D_{H} form an included angle θ1. In some embodiments, the plane D_{H} is substantially parallel with a front surface 202s of the substrate 202. In some embodiments, the included angle θ1 can be between about 48° and about 58°, but the disclosure is not limited to this. In some embodiments, the micro structures 216 can be continuous structures and include a wave profile as shown in FIG. 3. In some embodiments, the micro structures 216 can include discrete structure spaced apart from each other by the substrate 202.

In some embodiments, an ARC 218 is disposed over the substrate 202 on the back side 202B. And surfaces of the micro structures 216 are lined by the conformally formed ARC 218. In some embodiments, an insulating structure 270 is disposed over the ARC 218 on the back side 202B of the substrate 202, the insulating structure 270 includes a first surface 270a facing the front side 202F and a second surface 270b facing the back side 202B. The insulating structure 270 can be obtained by operations as mentioned and depicted in FIGS. 2A-2E, therefore those details are omitted in the interest of brevity. In some embodiments, the first surface 270a includes the wave pattern the same as the micro structures 216 in the cross-sectional view. In some embodiments, the second surface 270b includes a substantially even or flat surface as shown in FIG. 3, but the disclosure is not limited to this. For example, the second surface 270b can include a curved surface as shown in FIG. 1 in some embodiments.

In some embodiments, each of the pixel sensors 210 includes an optical structure 252 over the color filter 250 on the back side 202B. In some embodiments, the optical structure 252 includes a first sidewall 252a, and the first sidewall 252a and the plane D_{H} substantially parallel with the front surface 202s of the substrate 202 form an included angle θ2 greater than 0°. For example but not limited to, the included angle θ2 can be between about 35° and about 55°. In some embodiments, the optical structure 252 and the color filter 252 include a same material, and the optical structure 252 is protruded toward the back side 202B as shown in FIG. 3.

Referring to FIG. 4A, the optical structure 252 can be formed by the following operations. For example, the insulating structure 270 is disposed over the substrate 202 on the back side 202B and followed by disposing the low-n structure 240. Additionally, an etching operation can be performed to form a curved second surface after disposing the low-n structure 240 in some embodiments. Next, the color filter materials are disposed within the low-n structure 240. In some embodiments, the color filter materials cover the low-n structure 240. Subsequently, a shaping operation is performed to the color filter materials. The shaping operation can include any suitable operations such as masking/and lithography operations, therefore those details are omitted for brevity. After performing the shaping operation, the color filters 250 located within the low-n structure 240 are obtained and the optical structures 252 respectively over both of the color filter 250 and the low-n structure 240 are obtained. In other words, each of the optical structure 252 is formed to cover one of the color filter 250 and a portion of a top surface of the low-n structure 240. Further, each of the optical structure 252 include material the same as its underneath color filter 250.

Referring back to FIG. 3, due to the optical structure 252 over the color filter 250, the light L entering optical structure 252 and the color filter 250 is diffused, and thus longer light traveling distance is obtained. More importantly, micro-lens is no longer required in the BSI image sensor 200 due to the optical structure 252. Consequently, a height of the optical stack is reduced, and angle response is improved. Still referring to FIG. 3, the light L is not only diffused by the optical structure 252, but also dipped or tilted by the optical structure 252 and the micro structures 216 when entering the photodiode 212, and thus longer light traveling distance is obtained. Consequently, absorption of the photodiode 212 is increased. Further, since the light can be reflected back to the photodiode 212 by the DTI structure 220, it is taken that light is trapped within the photodiode 212 as shown in FIG. 3. Accordingly, more photons are absorbed, and the sensitivity of the BSI image sensor 200 is improved. Additionally, since the light traveling distance is extended, a thickness of the photodiode 212 or the substrate 202 can be reduced and thus process is further simplified and improved.

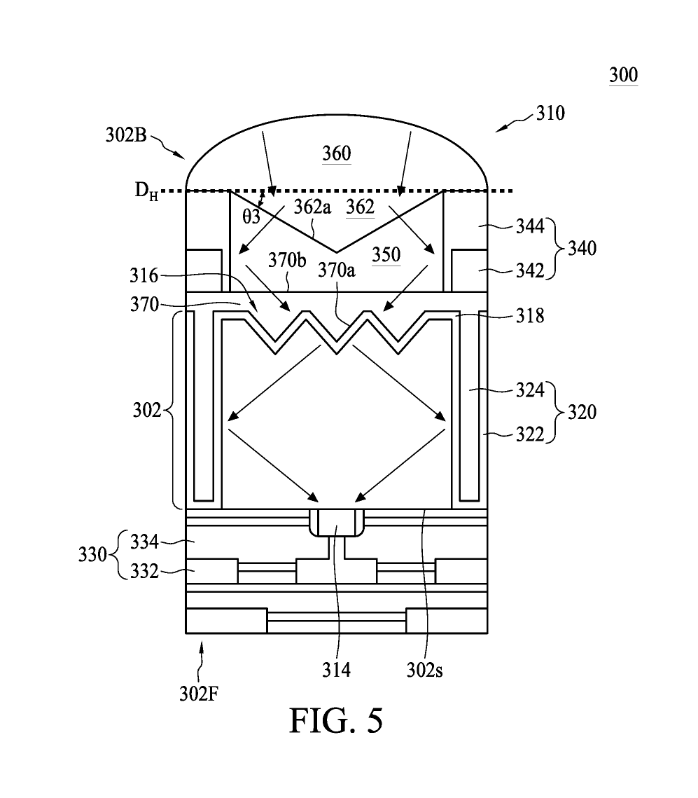

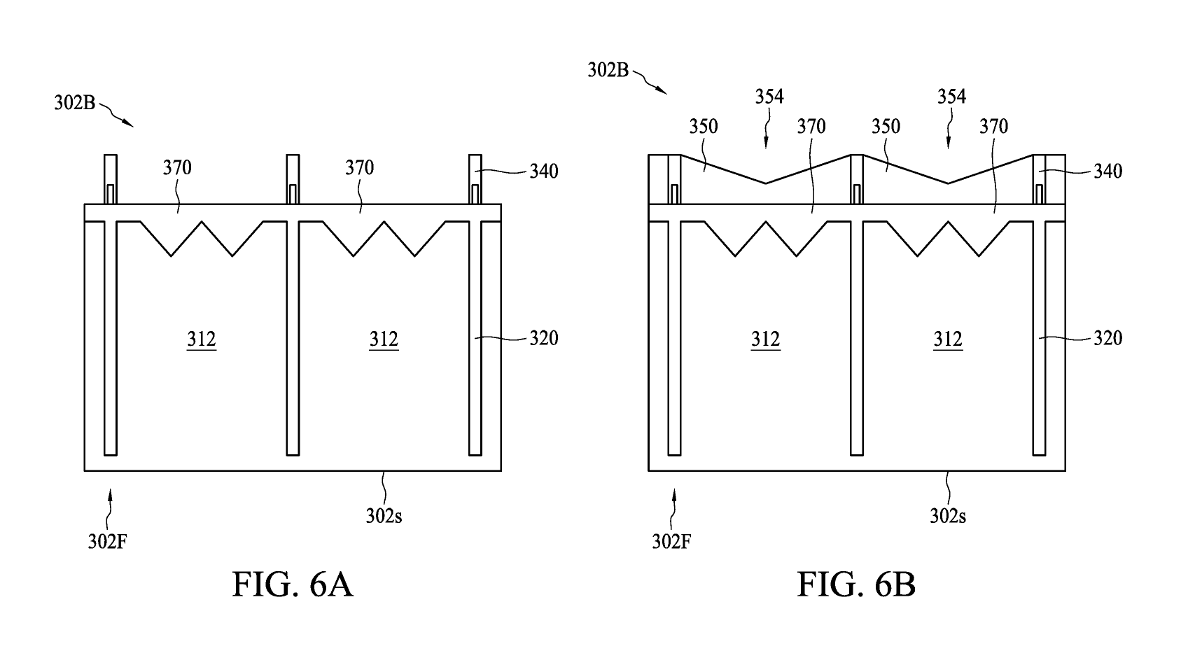

FIG. 5 is a cross-sectional view of a pixel sensor 310 of a BSI image sensor 300 according to aspects of the present disclosure in one or more embodiments, and FIGS. 6A-6B are a series of cross-sectional views of pixel sensors 310 of a BSI image sensor 300 at various fabrication stages constructed according to aspects of the present disclosure in one or more embodiments. It should be easily understood that same elements in FIG. 5 and FIGS. 6A-6E are designated by the same numerals. And elements the same in the BSI image sensor 300 and the BSI image sensor 100/200 can include the same material and/or formed by the same operations, and thus those details are omitted in the interest of brevity. As shown in FIG. 5, the BSI image sensor 300 includes a substrate 302, and the substrate 302 has a front side 302F and a back side 302B opposite to the front side 302F. The BSI image sensor 300 includes a plurality of pixel sensors 310 typically arranged within an array. A plurality of photo-sensing devices such as photodiodes 312 corresponding to the pixel sensors 310 is disposed in the substrate 202. The photodiodes 312 are arranged in rows and columns in the substrate 302. In other words, each of the pixel sensors 310 includes a photo-sensing device such as the photodiode 312. Further, logic device, such as transistor 314, is disposed over the front side 302F of the substrate 302 and configured to enable readout of the photodiodes 312.

An isolation structure 320 such as a DTI structure is disposed in the substrate 302 as shown in FIG. 5. In some embodiments, at least sidewalls of the deep trenches are lined by a coating 322 and the deep trenches are filled up by an insulating material 324. The DTI structure 320 provides optical isolation between neighboring pixel sensors 310, thereby serving as a substrate isolation grid and reducing cross-talk. A BEOL metallization stack 330 is disposed over the front side 302F of the substrate 302. The BEOL metallization stack 330 includes a plurality of metallization layers 332 stacked in an ILD layer 334. One or more contacts of the BEOL metallization stack 330 is electrically connected to the logic device 214. In some embodiments, another substrate (not shown) can be disposed between the metallization structure 330 and external connectors such as a ball grid array (BGA) (not shown). And the BSI image sensor 300 is electrically connected to other devices or circuits through the external connectors, but the disclosure is not limited to this.

In some embodiments, each of the pixel sensors 310 includes a plurality of micro structures 316 disposed over the back side 302B of the substrate 302 as shown in FIG. 5. In some embodiments, the micro structures 316 are tapered or rounded to obtain a wave pattern as shown in FIG. 5. As mentioned above, a sidewall of the micro structures 316 and a direction or a plane D_{H} form an included angle θ1 (as shown in FIG. 1). In some embodiments, the plane D_{H} is substantially parallel with a front surface 302s of the substrate 302. In some embodiments, the included angle θ1 can be between about 48° and about 58°, but the disclosure is not limited to this. In some embodiments, the micro structures 316 can be continuous structures and include a wave profile as shown in FIG. 5. In some embodiments, the micro structures 316 can include discrete structure spaced apart from each other by the substrate 302.

In some embodiments, an ARC 318 is disposed over the substrate 302 on the back side 302B. And surfaces of the micro structures 316 are lined by the conformally formed ARC 318. In some embodiments, an insulating structure 370 is disposed over the ARC 318 on the back side 302B of the substrate 302. The insulating structure 370 includes a first surface 370a facing the front side 302F and a second surface 370b facing the back side 302B. The insulating structure 370 can be obtained by operations as mentioned and depicted in FIGS. 2A-2E, therefore those details are omitted in the interest of brevity. In some embodiments, the first surface 370a includes the wave pattern the same as the micro structures 316 in the cross-sectional view. In some embodiments, the second surface 370b includes a substantially even or flat surface as shown in FIG. 5, but the disclosure is not limited to this. For example, the second surface 370b can include a curved surface as shown in FIG. 1 in some embodiments.

Referring to FIG. 5, in some embodiments, a plurality of color filters 350 corresponding to the pixel sensors 310 is disposed over the pixel sensors 310 on the back side 302B of the substrate 302. In other words, each of the pixel sensors 310 includes a color filter 350 over the photo-sensing device 312 on the back side 302B. Further, a low-n structure 340 is disposed between the color filters 350 in some embodiments. In some embodiments, the low-n structure 340 includes a grid structure and the color filters 350 are located within the grid. Thus the low-n structure 340 surrounds each color filter 350, and separates the color filters 350 from each other as shown in FIG. 5. The low-n structure 340 can be a composite structure including layers with a refractive index less than the refractive index of the color filters 350. In some embodiments, the low-n structure 340 can include a composite stack including at least a metal layer 342 and a dielectric layer 344 disposed over the metal layer 342. Due to the low refractive index, the low-n structure 340 serves as a light guide to direct or reflect light to the color filters 350. Consequently, the low-n structure 340 effectively increases the amount of the light incident into the color filters 350. Further, due to the low refractive index, the low-n structure 340 provides optical isolation between neighboring color filters 350.

Each of the color filters 350 is disposed over each of the corresponding photodiodes 312. The color filters 350 are assigned to corresponding colors or wavelengths of lights, and configured to filter out all but the assigned colors or wavelengths of lights. In some embodiments, a micro-lens 360 corresponding to each pixel sensor 310 is disposed over the color filter 350. It should be easily understood that locations and areas of each micro-lens 360 correspond to those of the color filter 350 or the pixel sensor 310 as shown in FIG. 5.

In some embodiments, each of the pixel sensors 310 includes an optical structure 362 sandwiched between the color filter 350 and the micro-lens 360 on the back side 302B. In some embodiments, the optical structure 362 includes a first sidewall 362a, and the first sidewall 362a and the plane D_{H} form an included angle θ3 greater than 0°. For example but not limited to, the included angle θ3 can be between about 35° and about 55°. In some embodiments, the optical structure 362 and the micro-lens 360 can include a same material, and each of the optical structures 362 is protruded toward the front side 302F as shown in FIG. 5.

Referring to FIG. 6A, the optical structure 352 can be formed by the following operations. For example, the insulating structure 370 is disposed over the substrate 302 on the back side 302B and followed by disposing the low-n structure 340. Additionally, an etching operation can be performed to form a curved second surface after disposing the low-n structure 340 in some embodiments. Next, the color filters 350 are disposed within the low-n structure 340. Subsequently, an etching operation can be performed to form a recess 354 in each of the color filters 350 as shown in FIG. 6B. In other words, each of the color filters 350 includes a recess 354 recessed or dented toward the front side 302F. After forming the recess 354, the micro lens 360 and the optical structure 362 are disposed. Accordingly, the optical structure 362 is disposed to fill the recess 354 while the micro-lens 360 is disposed over the optical structure 362, the color filter 350 and the low-n structure 340 as shown in FIG. 5.

Referring back to FIG. 5, due to the optical structure 362 between the micro-lens 360 and the color filter 350, the light L entering the micro-lens 360 is condensed, but the light L is then diffused by the optical structure 362, and thus longer light traveling distance is obtained. As shown in FIG. 5, the light L diffused by the optical structure 362, is then dipped or tilted by the micro structures 316 when entering the photodiode 312, and thus longer light traveling distance is obtained. Consequently, absorption of the photodiode 312 is increased. Further, since the light can be reflected back to the photodiode 312 by the DTI structure 320, it is taken that light is trapped within the photodiode 312 as shown in FIG. 5. Accordingly, more photons are absorbed, and the sensitivity of the BSI image sensor 300 is improved. Additionally, since the light traveling distance is extended, a thickness of the photodiode 312 or the substrate 302 can be reduced and thus process is further simplified and improved.

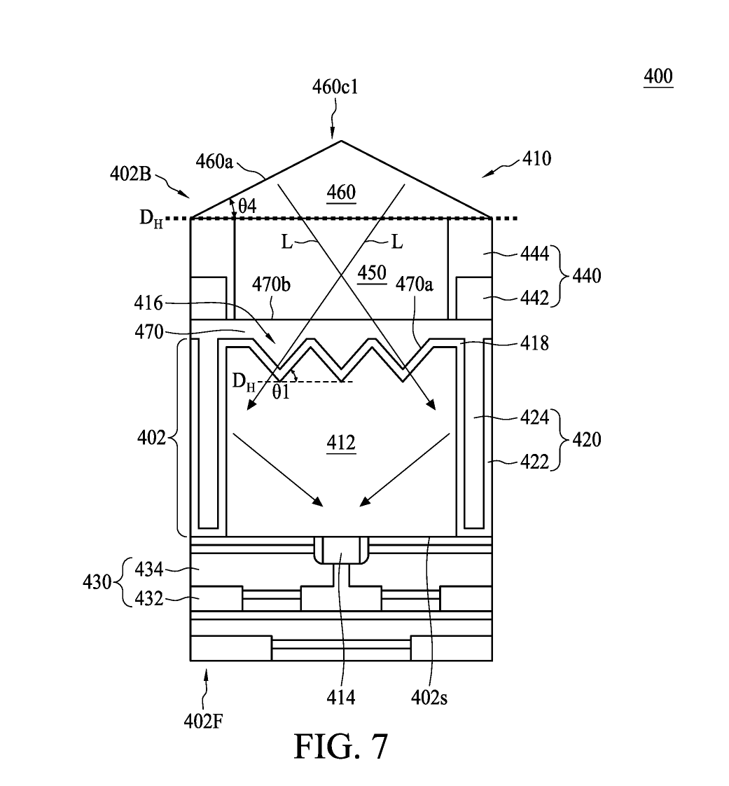

FIG. 7 is a cross-sectional view of a pixel sensor 410 of a BSI image sensor 400 according to aspects of the present disclosure in one or more embodiments. It should be noted that the same elements in the BSI image sensor 400 and the BSI image sensor 100/200/300 can include the same material and/or formed by the same operations, and thus those details are omitted in the interest of brevity. As shown in FIG. 7, the BSI image sensor 400 includes a substrate 402, and the substrate 402 has a front side 402F and a back side 402B opposite to the front side 402F. The BSI image sensor 400 includes a plurality of pixel sensors 410 typically arranged within an array. A plurality of photo-sensing devices such as photodiodes 412 corresponding to the pixel sensors 410 is disposed in the substrate 402. The photodiodes 412 are arranged in rows and columns in the substrate 402. In other words, each of the pixel sensors 410 includes a photo-sensing device such as the photodiode 412. Further, logic devices, such as transistors 414, are disposed over the front side 402F of the substrate 402 and configured to enable readout of the photodiodes 412.

An isolation structure 420 such as a DTI structure is disposed in the substrate 402 as shown in FIG. 7. In some embodiments, at least sidewalls of the deep trenches are lined by a coating 422 and the deep trenches are filled up by an insulating material 424. The DTI structure 420 provides optical isolation between neighboring pixel sensors 410, thereby serving as a substrate isolation grid and reducing cross-talk. A BEOL metallization stack 430 is disposed over the front side 402F of the substrate 402. The BEOL metallization stack 430 includes a plurality of metallization layers 432 stacked in an ILD layer 434. One or more contacts of the BEOL metallization stack 430 is electrically connected to the logic device 414. In some embodiments, another substrate (not shown) can be disposed between the metallization structure 430 and external connectors such as a ball grid array (BGA) (not shown). And the BSI image sensor 400 is electrically connected to other devices or circuits through the external connectors, but the disclosure is not limited to this.

In some embodiments, each of the pixel sensors 410 includes a plurality of micro structures 416 disposed over the back side 402B of the substrate 402 as shown in FIG. 7. In some embodiments, the micro structures 416 are tapered or rounded to obtain a wave pattern as shown in FIG. 7. As mentioned above, a sidewall of the micro structures 416 and a direction or a plane D_{H} form an included angle θ1. In some embodiments, the plane D_{H} is substantially parallel with a front surface 402s of the substrate 402. In some embodiments, the included angle θ1 can be between about 48° and about 58°, but the disclosure is not limited to this. In some embodiments, the micro structures 416 can be continuous structures and include a wave profile as shown in FIG. 7. In some embodiments, the micro structures 416 can include discrete structure spaced apart from each other by the substrate 402.

In some embodiments, an ARC 418 is disposed over the substrate 402 on the back side 402B. And surfaces of the micro structures 416 are lined by the conformally formed ARC 418. In some embodiments, an insulating structure 470 is disposed over the ARC 418 on the back side 402B of the substrate 402, the insulating structure 470 includes a first surface 470a facing the front side 402F and a second surface 470b facing the back side 402B. The insulating structure 470 can be obtained by operations as mentioned and depicted in FIGS. 2A-2E, therefore those details are omitted in the interest of brevity. In some embodiments, the first surface 470a includes the wave pattern the same as the micro structures 416 in the cross-sectional view. In some embodiments, the second surface 470b includes a substantially even surface as shown in FIG. 7, but the disclosure is not limited to this. For example, the second surface 470b can include a curved surface as shown in FIG. 1 in some embodiments.

Referring to FIG. 7, in some embodiments, a plurality of color filters 450 corresponding to the pixel sensors 410 is disposed over the pixel sensors 410 on the back side 402B of the substrate 402. In other words, each of the pixel sensors 410 includes a color filter 450 over the photo-sensing device 412 on the back side 402B. Further, a low-n structure 440 is disposed between the color filters 450 in some embodiments. In some embodiments, the low-n structure 440 includes a grid structure and the color filters 450 are located within the grid. Thus the low-n structure 440 surrounds each color filter 450, and separates the color filters 450 from each other as shown in FIG. 7. The low-n structure 440 can be a composite structure including layers with a refractive index less than the refractive index of the color filters 450. In some embodiments, the low-n structure 440 can include a composite stack including at least a metal layer 442 and a dielectric layer 444 disposed over the metal layer 442. Due to the low refractive index, the low-n structure 440 serves as a light guide to direct or reflect light to the color filters 450. Consequently, the low-n structure 440 effectively increases the amount of the light incident into the color filters 450. Further, due to the low refractive index, the low-n structure 440 provides optical isolation between neighboring color filters 450. Each of the color filters 450 is disposed over each of the corresponding photodiodes 412. The color filters 450 are assigned to corresponding colors or wavelengths of lights, and configured to filter out all but the assigned colors or wavelengths of lights.

In some embodiments, each of the pixel sensors 410 includes an optical structure 460 disposed over the color filter 450 and the low-n structure 440. In some embodiments, the optical structure 460 includes materials used to form micro-lens. In other words, the optical structure 460 can include a micro-lens. In some embodiments, the optical structure 460 includes a first sidewall 460a, and the first sidewall 460a and the plane D_{H} form an included angle θ4 greater than 0°. In some embodiments, the first sidewall 460a and the color filter 450 form the included angle θ4. In some embodiments, the included angle θ4 can be between about 35° and about 55°, but the disclosure is not limited to this. In some embodiments, the optical structure 460 is protruded toward the back side 402B as shown in FIG. 7.

As shown in FIG. 7, due to the optical structure 460 disposed over the color filter 450, the light L entering the micro-lens 460 is dipped or tilted by the optical structure 460. Further, the light L is then dipped or tilted by the micro structures 416 when entering the photodiode 412, and thus longer light traveling distance is obtained. Consequently, absorption of the photodiode 412 is increased. Further, since the light can be reflected back to the photodiode 412 by the DTI structure 420, it is taken that light is trapped within the photodiode 412 as shown in FIG. 7. Accordingly, more photons are absorbed, and the sensitivity of the BSI image sensor 400 is improved. Additionally, since the light traveling distance is extended, a thickness of the photodiode 412 or the substrate 402 can be reduced and thus process is further simplified and improved.

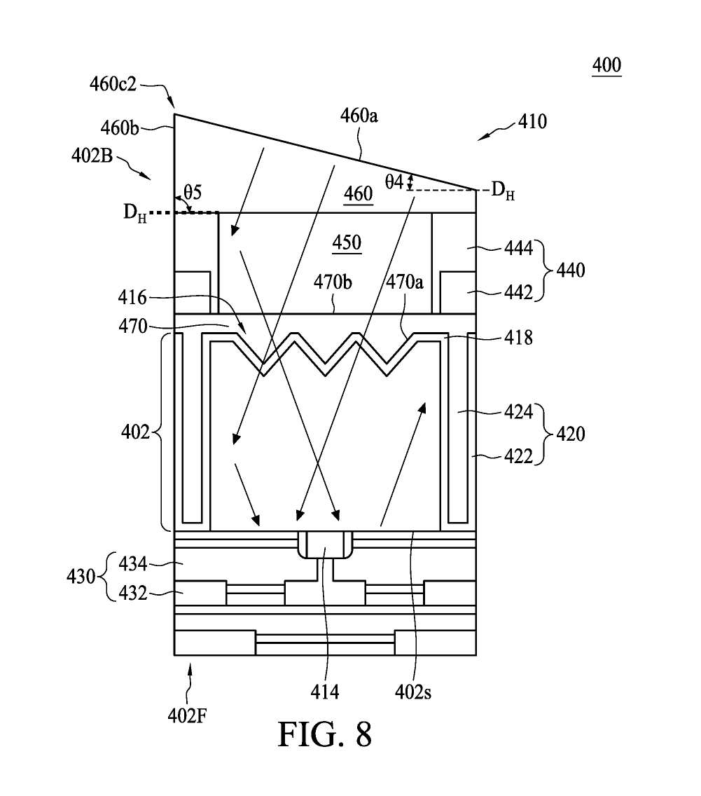

Referring to FIGS. 7 and 8, which is a cross-sectional view of a pixel sensor 410 of a BSI image sensor 400 according to aspects of the present disclosure in some embodiments. It should be noted that in some embodiments, all of the sidewalls of the optical structure 460 and the plane D_{H} (or the color filter 450) can form the same included angle θ4, as shown in FIG. 7, and thus all sidewalls are referred to as the first sidewall 460a. Additionally, the first sidewalls 460a are contact to form a vertex 460c1 as shown in FIG. 7. However, in some embodiments, the optical structure 460 can include a first sidewall 460a and a second sidewall 460b. The first sidewall 460a and the direction D_{H} (or the color filter 450) form the included angle θ4, the second sidewall 460b the direction D_{H} (or the color filter 450) form an included angle θ5, and the included angle θ5 is different from the included angle θ4. In some embodiments, the included angle θ5 is greater than the included angle θ4. Further, the first sidewall 460a and the second sidewall 460b are contact to form a vertex 460c2 as shown in FIG. 8.

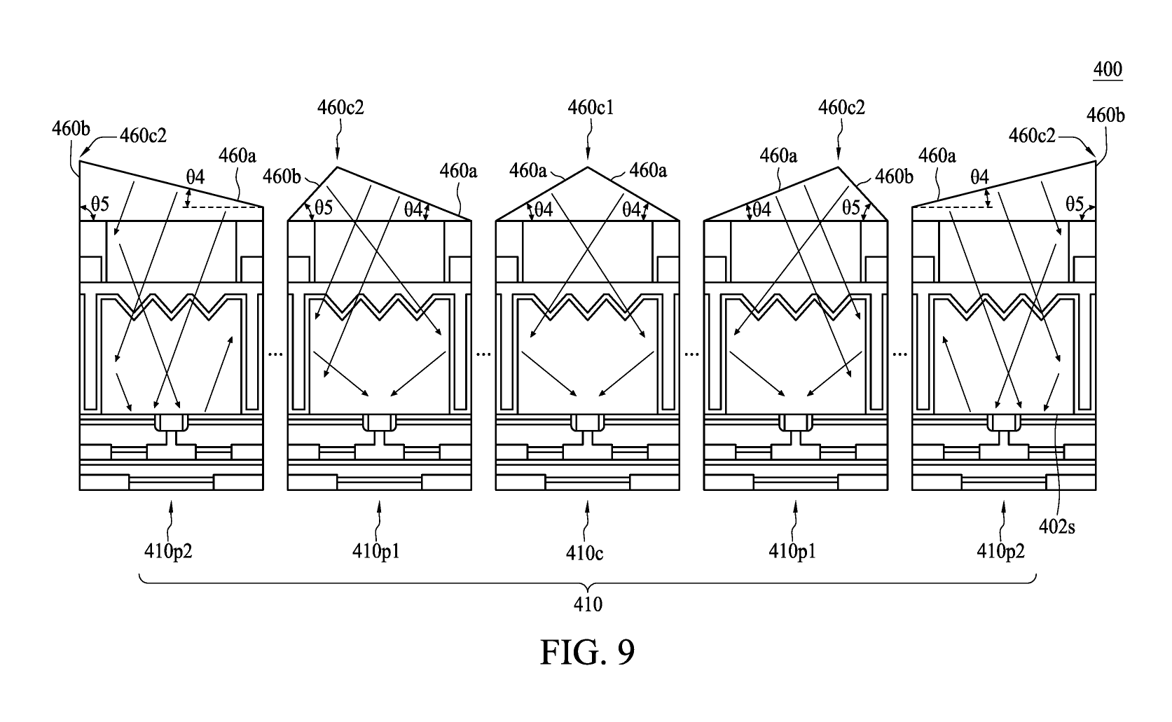

Referring to FIG. 9, which is a cross-sectional view of a plurality of pixel sensors 410 of the BSI image sensor 400 according to aspects of the present disclosure in some embodiments. It is well-known to those skilled in the art that the pixel sensors 410 are arranged in an array of rows and columns, therefore there are pixel sensors 410 located in the center region of the array and also pixel sensors 410 located in the peripheral and edge region of the array. More importantly, the light entering the pixel sensors 410 may include different incident angles depending on the locations of the pixel sensors 410. Therefore, in some embodiments, the included angle θ5 formed by the second sidewall 460b and the plane D_{H} (or the color filter 450) is tunable. In some embodiments, the pixel sensor(s) 410c located in the center region of the array can include only the first sidewalls 460a and the included angle θ4, and the pixel sensor(s) 410p1 located around the center region can include the first sidewall 460a and the second sidewall 460b. More importantly, the included angle θ5 of the pixel sensors 410 is getting larger and larger when the pixel sensor 410 is located farther and farther away from the center region. As shown in FIG. 9, the included angle θ5 of the pixel sensors 410p2, which are located at the peripheral or edge region of the array, is greater than the included angle θ5 of the pixel sensors 410p1, which are located between the pixel sensors 410c and the pixel sensors 410p2. In some embodiments, the include angle θ5 of the pixel sensors 410p2 located at the edge region of the array can be 90°, but the disclosure is not limited to this. Additionally, the vertex 460c is also tunable according to the some embodiments of the disclosure. For example, the vertex 460c1 of the pixel sensor 410c located in the center region of the array is also located in the center of the optical structure 460, but the vertex 460c2 is getting farther and farther away from the center region when the pixel sensor 410 is located farther and farther away from the center region. As mentioned above, since the light entering the pixel sensors 410 may include different incident angles depending on the locations of the pixel sensors 410. The included angle θ5 is tunable such that the first sidewall 460a provides sufficient large surface to direct the incident light. Consequently, the light L is then dipped or tilted by the micro structures 416 when entering the photodiode 412, and thus longer light traveling distance is obtained.

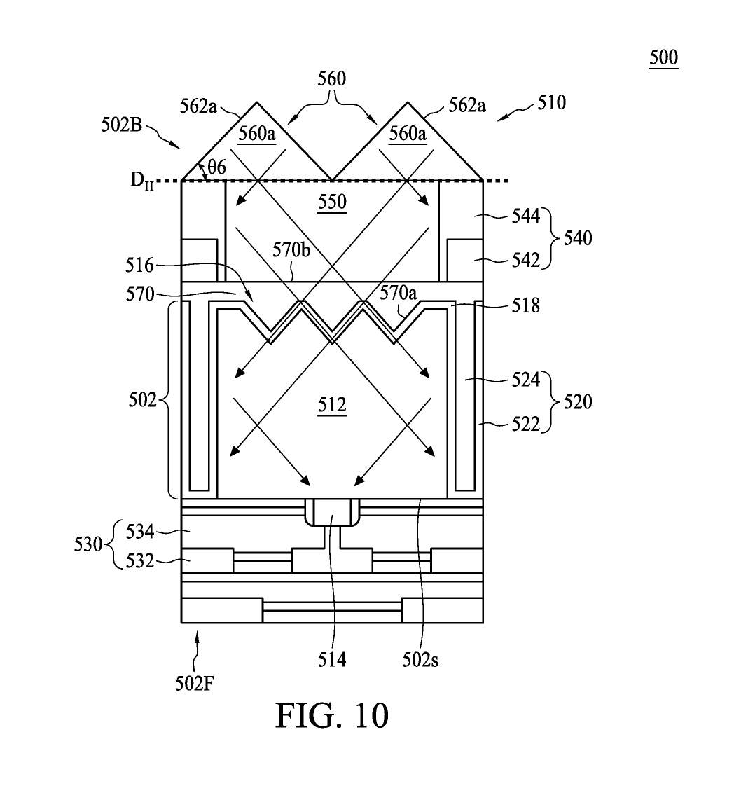

FIGS. 10-12 are cross-sectional views of a pixel sensor 510 of a BSI image sensor 500 according to aspects of the present disclosure in one or more embodiments. It should be noted that the same elements in the BSI image sensor 500 and the BSI image sensor 100/200/300/400 can include the same material and/or formed by the same operations, and thus those details are omitted in the interest of brevity. As shown in FIGS. 10-12, the BSI image sensor 500 includes a substrate 502, and the substrate 502 has a front side 502F and a back side 502B opposite to the front side 502F. The BSI image sensor 500 includes a plurality of pixel sensors 510 typically arranged within an array. A plurality of photodiode 512 corresponding to the pixel sensor 510 is disposed in the substrate 502. The photodiodes 512 are arranged in rows and columns in the substrate 502. Further, logic devices, such as transistors 514, are disposed over the front side 502F of the substrate 502 and configured to enable readout of the photodiodes 512.

An isolation structure 520 such as a DTI structure is disposed in the substrate 502 as shown in FIGS. 10-12. In some embodiments, at least sidewalls of the deep trenches are lined by a coating 522 and the deep trenches are filled up by an insulating material 524. The DTI structure 520 provides optical isolation between neighboring pixel sensors 510, thereby serving as a substrate isolation grid and reducing cross-talk. A BEOL metallization stack 530 is disposed over the front side 502F of the substrate 502. The BEOL metallization stack 530 includes a plurality of metallization layers 532 stacked in an ILD layer 534. One or more contacts of the BEOL metallization stack 530 is electrically connected to the logic device 514. In some embodiments, another substrate (not shown) can be disposed between the metallization structure 530 and external connectors such as a ball grid array (BGA) (not shown). And the BSI image sensor 500 is electrically connected to other devices or circuits through the external connectors, but the disclosure is not limited to this.

In some embodiments, each of the pixel sensors 510 includes a plurality of micro structures 516 disposed over the back side 502B of the substrate 502 as shown in FIGS. 10-12. In some embodiments, the micro structures 516 are tapered or rounded to obtain a wave pattern as shown in FIG. 10. As mentioned above, a sidewall of the micro structures 516 and a direction or a plane D_{H} substantially parallel with a front surface 502s of the substrate 502 form an included angle θ1 as shown in FIG. 1, and the included angle θ1 can be between about 48° and about 58°, but the disclosure is not limited to this. In some embodiments, the micro structures 516 can be continuous structures and include a wave profile as shown in FIGS. 10-12. In some embodiments, the micro structures 516 can include discrete structure spaced apart from each other by the substrate 502.

In some embodiments, an ARC 518 is disposed over the substrate 502 on the back side 502B. And surfaces of the micro structures 516 are lined by the conformally formed ARC 518. In some embodiments, an insulating structure 570 is disposed over the ARC 518 on the back side 502B of the substrate 502, the insulating structure 570 includes a first surface 570a facing the front side 502F and a second surface 570b facing the back side 502B. The insulating structure 570 can be obtained by operations as mentioned and depicted in FIGS. 2A-2E, therefore those details are omitted in the interest of brevity. In some embodiments, the first surface 570a includes the wave pattern the same as the micro structures 516 in the cross-sectional view. In some embodiments, the second surface 570b includes a substantially even surface as shown in FIGS. 10-12, but the disclosure is not limited to this. For example, the second surface 570b can include a curved surface as shown in FIG. 1 in some embodiments.

Referring to FIGS. 10-12, in some embodiments, a plurality of color filters 550 corresponding to the pixel sensors 510 is disposed over the pixel sensors 510 on the back side 502B of the substrate 502. Further, a low-n structure 540 is disposed between the color filters 550 in some embodiments. In some embodiments, the low-n structure 540 includes a grid structure and the color filters 550 are located within the grid. Thus the low-n structure 540 surrounds each color filter 550, and separates the color filters 550 from each other as shown in FIG. 10. The low-n structure 540 can be a composite structure including layers with a refractive index less than the refractive index of the color filters 550. In some embodiments, the low-n structure 540 can include a composite stack including at least a metal layer 542 and a dielectric layer 544 disposed over the metal layer 542. Due to the low refractive index, the low-n structure 540 serves as a light guide to direct or reflect light to the color filters 550. Consequently, the low-n structure 540 effectively increases the amount of the light incident into the color filters 550. Further, due to the low refractive index, the low-n structure 540 provides optical isolation between neighboring color filters 550. Each of the color filters 550 is disposed over each of the corresponding photodiodes 512. The color filters 550 are assigned to corresponding colors or wavelengths of lights, and configured to filter out all but the assigned colors or wavelengths of lights.

In some embodiments, each pixel sensor 510 includes a plurality of optical structures 560 disposed over the color filter 550 on the back side 502B. In some embodiments, the optical structures 560 include materials used to form micro-lens. In other words, the optical structures 560 can include micro-lenses 560. It should be easily understood that amounts, locations and areas of the plurality of micro-lenses 560 of one pixel sensor 510 correspond to the underneath color filter 550 as shown in FIGS. 10-12. For example, a bottom area of each of the plurality of micro-lenses 560 is less than a top area of its underneath color filter 550. In some embodiments, a width of each of the plurality of micro-lenses 560 substantially equals to a half of a width of the pixel sensor 510, but the disclosure is not limited to this. In some embodiments, a sum of bottom areas of the plurality of micro-lenses 560 is greater than the top area of the color filter 550 under the plurality of micro-lenses 560. In some embodiments, at least one of the plurality of the micro-lenses 560a covers a portion of the low-n structure 540, as shown in FIGS. 10-12.

In some embodiments, each of the micro-lenses 560 includes a prism shape, as shown in FIG. 10. The prism-shaped micro-lenses 560a respectively include a first sidewall 562a, and the first sidewall 562a and the plane D_{H} substantially parallel with the front surface 502s of the substrate 502 form an included angle θ6 greater than 0°. In some embodiments, the first sidewall 562a and the color filter 550 form the included angle θ6. In some embodiments, the included angle θ6 can be between about 35° and about 55°, but the disclosure is not limited to this. In some embodiments, the micro-lenses 560a are protruded toward the back side 502B as shown in FIG. 10. Additionally, a height of the micro-lenses 560a depends on the pixel size and the included angle θ6.

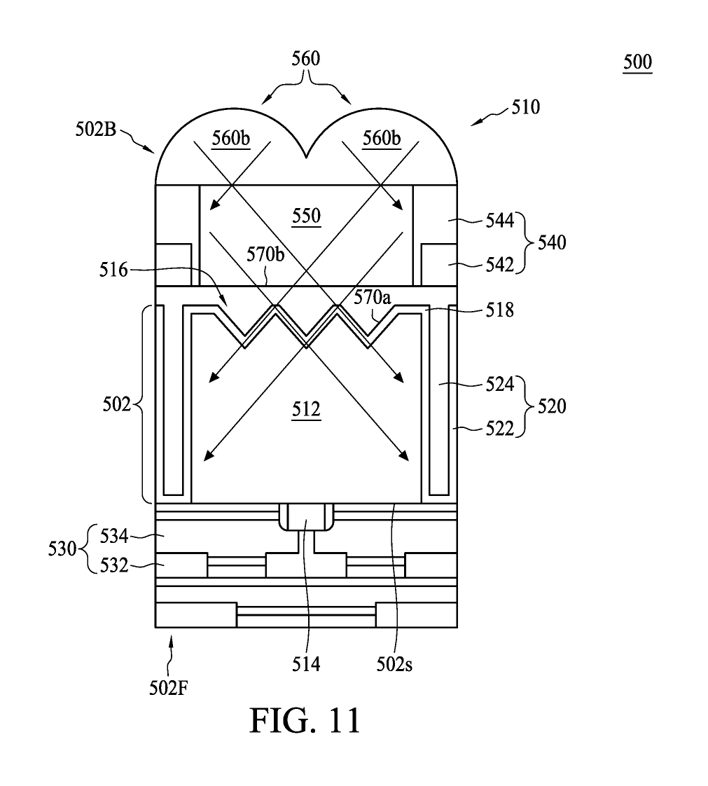

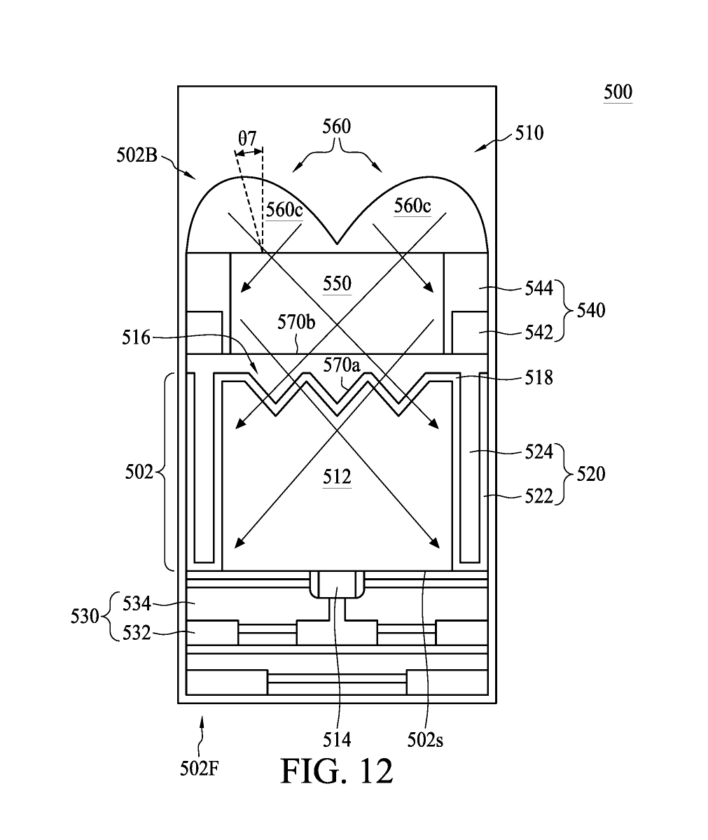

In some embodiments, each of the micro-lenses 560 includes a semicircle shape, as shown in FIG. 11. The semicircular micro-lenses 560b respectively include a curved surface toward the back side 502B. In some embodiments, each of the micro-lenses 560 includes a half-droplet shape or a half-ellipse shape as shown in FIG. 12. The half-droplet shaped or half-elliptical shaped micro-lenses 560c respectively include a curved surface toward the back side 502B. Further, each of the micro-lens 560c includes a semi-major axis, the semi-major axis and a normal vector of the color filter 550 form an included angle θ7, and the included angle θ7 is between about 0° and about 45°. Additionally, a height of the micro-lenses 560b or 560c depends on the pixel size and the included angle θ7.

As shown in FIGS. 10-12, due to the plurality of micro-lenses 560 disposed over the one color filter 550, the light L entering the micro-lenses 560 is dipped or tilted. Further, the light L is then dipped or tilted by the micro structures 516 when entering the photodiode 512, and thus longer light traveling distance is obtained. Consequently, absorption of the photodiode 512 is increased. Further, since the light can be reflected back to the photodiode 512 by the DTI structure 520, it is taken that light is trapped within the photodiode 412 as shown in FIGS. 10-12. Accordingly, more photons are absorbed, and the sensitivity of the BSI image sensor 500 is improved. Additionally, since the light traveling distance is extended, a thickness of the photodiode 512 or the substrate 502 can be reduced and thus process is further simplified and improved.

Accordingly, the present disclosure therefore provides a pixel sensor of a BSI image sensor including an insulating structure including a curved surface protruded toward a front side of the BSI sensor, thus light is further condensed in some embodiments. The present disclosure further provides a BSI image sensor including an optical structure including a material the same with the color filer or the micro-lens. The optical structure serves as light guide, and longer light traveling distance is created in the photodiode by the optical structure in some embodiments. Accordingly, more photons are absorbed. Further, the disclosure therefore provides a BSI image sensor including a plurality of micro-lens over one color filter, and longer light traveling distance is created in the photodiode by the plurality of micro-lens in some embodiments. In other words, since the light is traveling with large angle in the pixel sensor, the sensitivity and angular response are improved.

In some embodiments, a BSI image sensor is provided. The BSI image sensor includes a substrate including a front side and a back side opposite to the front side, a pixel sensor in the substrate, an insulating structure disposed over the substrate on the back side, a color filter over the substrate on the back side, and a micro-lens over the color filter on the back side. The insulating structure includes a first surface facing the front side and a second surface facing the back side, and the second surface includes a curved surface curved toward the front side.

In some embodiments, a BSI image sensor is provided. The BSI image sensor includes a substrate including a front side and a back side opposite to the front side, and a plurality of pixel sensors arranged in an array. Each of the pixel sensors includes a photo-sensing device in the substrate, a color filter over the pixel sensor on the back side, and an optical structure over the color filter. The optical structure includes a first sidewall, and the first sidewall and a plane substantially parallel with a front surface of the substrate form an included angel greater than 0°.

In some embodiments, a BSI image sensor is provided. The BSI image sensor includes a substrate including a front side and a back side opposite to the front side, a pixel sensor in the substrate, a color filter over the substrate on the back side, and a plurality of micro-lenses over the color filter. A bottom area of each of the plurality of micro-lenses is less than a top area of the color filter, and a sum of the bottom areas of the plurality of micro-lenses is greater than the top area of the color filter.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A back side illumination (BSI) image sensor comprising:
a substrate comprising a front side and a back side opposite to the front side;
a pixel sensor in the substrate;
an insulating structure disposed over the substrate on the back side, the insulating structure comprising a first surface facing the front side and a second surface facing the back side, and the second surface comprising a curved surface curved toward the front side;
a color filter over the substrate on the back side;
a micro-lens over the color filter on the back side; and
a plurality of micro structures disposed over the substrate on the back side, wherein the color filter is disposed directly over the plurality of micro structures.

2. (canceled)

3. The BSI image sensor of claim 1, wherein a sidewall of the micro structures and a plane substantially parallel with a front surface of the substrate form an included angle, and the included angle is between about 48° and about 58°.

4. The BSI image sensor of claim 1, wherein the first surface of the insulating structure covers the micro structures and comprises a wave pattern in a cross-sectional view.

5. A back side illumination (BSI) image sensor comprising:
a substrate comprising a front side and a back side opposite to the front side; and
a plurality of pixel sensors arranged in an array, and each of the pixel sensors comprising:
a photo-sensing device in the substrate;
a color filter over the photo-sensing device on the back side; and
an optical structure over the color filter, wherein the optical structure comprises a first sidewall, the first sidewall and a plane substantially parallel with a front surface of the substrate form an included angle greater than 0°, and the optical structure includes a vertex disposed directly over the photo-sensing device.

6. The BSI image sensor of claim 5, wherein the included angle is between about 35° and about 55°.

7. The BSI image sensor of claim 5, wherein the optical structures and the color filters comprise a same material, and each of the optical structures is protruded toward the back side.

8. The BSI image sensor of claim 7, further comprising a plurality of low-n structures disposed over the substrate on the back side, and the low-n structure surrounding and separating the color filters.

9. The BSI image sensor of claim 8, wherein each of the optical structures covers top surfaces of the low-n structures.

10. The BSI image sensor of claim 5, wherein each of the pixel sensors further comprises a micro-lens disposed over the color filter on the backside.

11. The BSI image sensor of claim 10, wherein the optical structures and the micro-lens comprise a same material.

12. The BSI image sensor of claim 11, wherein each of the color filters comprises a recess recessed toward the front side.

13. The BSI image sensor of claim 12, wherein the optical structure is disposed between the color filter and the micro-lens, and the optical structure is located in the recess.

14. The BSI image sensor of claim 5, wherein each of the optical structures comprises a micro-lens.

15. The BSI image sensor of claim 14, wherein each of the optical structures further comprises a second sidewall, and the first sidewall and the second sidewall are in contact to form the vertex.

16. The BSI images sensor of claim 15, wherein a location of the vertex of each of the optical structures in the array is tunable.

17. A back side illumination (BSI) image sensor comprising:
a substrate comprising a front side and a back side opposite to the front side;
a pixel sensor in the substrate;
a color filter over the substrate on the back side;
a plurality of micro-lenses over the color filter,
wherein a bottom area of each of the micro-lenses is less than a top area of the color filter, a sum of the bottom areas of the plurality of micro-lenses is greater than the top area of the color filter, and each micro-lens overlaps a portion of the color filter.

18. The BSI image sensor of claim 17, wherein each of the micro-lenses comprises a sidewall, and the sidewall and a plane substantially parallel with a front surface of the substrate form an included angle between about 35° and 55°.

19. The BSI image sensor of claim 17, wherein each of the micro-lenses comprises a prism shape.

20. The BSI image sensor of claim 17, wherein each of the micro-lens comprises a semi-major axis, and the semi-major axis and a normal vector of the color filter form an included angle, and the included angle is between about 0° and about 45°.

21. The BSI image sensor of claim 5, wherein the vertex points to the front side or the back side.
